(19) United States
(12) Patent Application Publication
(10) Pub. No.: US 2023/0177897 A1
(43) Pub. Date: Jun. 8, 2023

(54) STORAGE DEVICE AND METHOD OF OPERATING THE SAME

(71) Applicant: SK hynix Inc., Gyeonggi-do (KR)

(72) Inventor: In Jong JANG, Gyeonggi-do (KR)

(21) Appl. No.: 17/737,196

(22) Filed: May 5, 2022

(30) Foreign Application Priority Data
Dec. 8, 2021 (KR) 10-2021-0175068

(51) Int. Cl. G07C 5/08; G06F 11/07; G06F 12/02; G07C 5/00

(52) U.S. Cl. CPC G07C 5/0841; G06F 11/0757; G06F 12/0253; G07C 5/008

(57) ABSTRACT

Provided herein is a storage system and a method of operating the same. A memory controller for controlling a memory device including a plurality of memory blocks may include a sensor module, a watchdog timer, and a write controller. The sensor module may be configured to output a sensing value measured based on movement of a vehicle. The watchdog timer may be turned on from a time point at which the sensing value moves outside of a normal range. The write controller may be configured to store log information buffered in the memory controller into a memory block selected from among the plurality of memory blocks, the log information being obtained from a time point at which the watchdog timer is turned on to a time point at which the watchdog timer is turned off.

### CROSS-REFERENCE TO RELATED APPLICATION

The present application claims priority under 35 U.S.C. § 119(a) to Korean patent application number 10-2021-0175068, filed on Dec. 8, 2021, the entire disclosure of which is incorporated herein by reference.

### BACKGROUND

### 1. Field of Invention

Various embodiments of the present disclosure generally relate to an electronic device, and more particularly to a storage device and a method of operating the storage device.

### 2. Description of Related Art

A storage device is a device which stores data under the control of a host device, such as a computer or a smartphone. The storage device may include a memory device in which data is stored and a memory controller which controls the memory device. Such memory devices are classified into a volatile memory device and a nonvolatile memory device.

The volatile memory device is a memory device in which data is stored only when power is supplied and in which stored data is lost when the supply of power is interrupted. Examples of the volatile memory device include a static random access memory (SRAM) and a dynamic random access memory (DRAM).

The nonvolatile memory device is a memory device in which stored data is retained even when the supply of power is interrupted. Examples of the nonvolatile memory device include a read only memory (ROM), a programmable ROM (PROM), an electrically programmable ROM (EPROM), an electrically erasable and programmable ROM (EEPROM), and a flash memory.

### SUMMARY

Various embodiments of the present disclosure are directed to a storage device for automatically recording log information depending on a sensor value and a method of operating the storage device.

An embodiment of the present disclosure may provide for a memory controller for controlling a memory device including a plurality of memory blocks. The memory controller may include a sensor module, a watchdog timer, and a write controller. The sensor module may be configured to output a sensing value measured based on movement of a vehicle. The watchdog timer may be turned on from a time point at which the sensing value moves outside of a normal range. The write controller may be configured to store log information buffered in the memory controller into a memory block selected from among the plurality of memory blocks, the log information being obtained from a time point at which the watchdog timer is turned on to a time point at which the watchdog timer is turned off.

An embodiment of the present disclosure may provide for a storage device. The storage device may include a memory device and a memory controller. The memory device may include a plurality of memory blocks. The memory controller configured to control the memory device to store log information of the storage device into a memory block selected from among the plurality of memory blocks, wherein the memory controller is further configured to: measure a sensing value based on movement of a vehicle, and obtain, from a first time point at which the sensing value moves outside of a normal range, the log information during a preset time or the log information until the sensing value returns to the normal range.

An embodiment of the present disclosure may provide for a method of operating a storage device including a plurality of memory blocks. The method may include measuring a sensing value based on movement of a vehicle, turning on a watchdog timer from a time point at which the sensing value moves outside of a normal range, and storing log information of the storage device into a memory block selected from among the plurality of memory blocks, the log information being obtained from a time point at which the watchdog timer is turned on to a time point at which the watchdog timer is turned off.

An embodiment of the present disclosure may provide for a method of a recording system mounted on a moving object. The operating method comprises sensing a physical movement of the object to generate a sensing value and recording, when the value becomes beyond a range, information representing at least the movement for a predetermined time amount or until the value falls within the range.

### BRIEF DESCRIPTION OF THE DRAWINGS

FIG. 1 is a diagram illustrating a storage device according to an embodiment of the present disclosure.

FIG. 2 is a diagram illustrating the structure of the memory device of FIG. 1 according to an embodiment of the present disclosure.

FIG. 3 is a diagram illustrating a memory cell array of FIG. 2 according to an embodiment of the present disclosure.

FIG. 4 is a diagram illustrating the configuration and operation of a memory controller according to an embodiment of the present disclosure.

FIG. 5 is a diagram illustrating log information according to an embodiment of the present disclosure.

FIG. 6 is a diagram illustrating a garbage collection operation performed on target blocks according to an embodiment of the present disclosure.

FIG. 7 is a flowchart illustrating a garbage collection operation according to an embodiment of the present disclosure.

FIG. 8 is a flowchart illustrating a garbage collection operation according to an embodiment of the present disclosure.

FIG. 9 is a flowchart illustrating on and off operation of a watchdog timer according to an embodiment of the present disclosure.

FIG. 10 is a flowchart illustrating the operation of a storage device according to an embodiment of the present disclosure.

FIG. 11 is a diagram illustrating the memory controller of FIG. 1 according to an embodiment of the present disclosure.

FIG. 12 is a block diagram illustrating a memory card system to which a storage device according to an embodiment of the present disclosure is applied.

FIG. 13 is a block diagram illustrating a solid state drive (SSD) system to which a storage device according to an embodiment of the present disclosure is applied.

FIG. 14 is a block diagram illustrating a user system to which a storage device according to an embodiment of the present disclosure is applied.

### DETAILED DESCRIPTION

Specific structural or functional descriptions in the embodiments of the present disclosure introduced in this specification describe embodiments according to the concept of the present disclosure. The embodiments according to the concept of the present disclosure may be practiced in various forms, and should not be construed as being limited to the embodiments described in the specification.

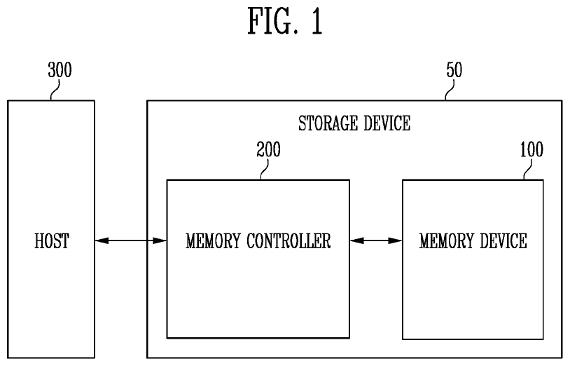

FIG. 1 is a diagram illustrating a storage device according to an embodiment of the present disclosure.

Referring to FIG. 1, a storage device 50 may include a memory device 100 and a memory controller 200 which controls the operation of the memory device. The storage device 50 may be a device which stores data under the control of a host 300, such as a mobile phone, a smartphone, an MP3 player, a laptop computer, a desktop computer, a game console, a television (TV), a tablet PC, or an in-vehicle infotainment system.

The storage device 50 may be manufactured as any one of various types of storage devices depending on a host interface that is a scheme for communication with the host 300. The storage device 50 may be implemented as one of various types of storage devices, for example, a solid state drive (SSD), a multimedia card such as an MMC, an embedded MMC (eMMC), a reduced size MMC (RS-MMC), or a micro-MMC, a secure digital card such as an SD, a mini-SD, or a micro-SD, a universal serial bus (USB) storage device, a universal flash storage (UFS) device, a personal computer memory card international association (PCMCIA) card-type storage device, a peripheral component interconnection (PCI)-card type storage device, a PCI express (PCI-e or PCIe) card-type storage device, a compact flash (CF) card, a smart media card, and a memory stick.

The storage device 50 may be manufactured in any of various types of package forms. For example, the storage device 50 may be manufactured in any of various types of package forms, such as package on package (POP), system in package (SIP), system on chip (SOC), multi-chip package (MCP), chip on board (COB), wafer-level fabricated package (WFP), and wafer-level stack package (WSP).

The memory device 100 may store data. The memory device 100 is operated in response to the control of the memory controller 200. The memory device 100 may include a memory cell array including a plurality of memory cells which store data.

Each of the memory cells may be implemented as a single-level cell (SLC) capable of storing a single data bit, a multi-level cell (MLC) capable of storing two data bits, a triple-level cell (TLC) capable of storing three data bits, or a quad-level cell (QLC) capable of storing four data bits.

The memory cell array may include a plurality of memory blocks. Each memory block may include a plurality of memory cells. A single memory block may include a plurality of pages. In an embodiment, each page may be a unit by which data is stored in the memory device 100 or by which data stored in the memory device 100 is read.

A memory block may be a unit by which data is erased. In an embodiment, the memory device 100 may take many alternative forms, such as a double data rate synchronous dynamic random access memory (DDR SDRAM), a low power double data rate fourth generation (LPDDR4) SDRAM, a graphics double data rate (GDDR) SDRAM, a low power DDR (LPDDR) SDRAM, a Rambus dynamic random access memory (RDRAM), a NAND flash memory, a vertical NAND flash memory, a NOR flash memory device, a resistive RAM (RRAM), a phase-change RAM (PRAM), a magnetoresistive RAM (MRAM), a ferroelectric RAM (FRAM), or a spin transfer torque RAM (STT-RAM). In the present disclosure, for convenience of description, a description will be made based on the memory device 100 being a NAND flash memory.

The memory device 100 may receive a command and an address from the memory controller 200, and may access the area of the memory cell array, selected by the address. That is, the memory device 100 may perform an operation indicated by the command on the area selected by the address. For example, the memory device 100 may perform a write operation (i.e., program operation), a read operation, and an erase operation. During a program operation, the memory device 100 may program data to the area selected by the address. During a read operation, the memory device 100 may read data from the area selected by the address. During an erase operation, the memory device 100 may erase data stored in the area selected by the address.

The memory controller 200 controls the overall operation of the storage device 50.

When power is applied to the storage device 50, the memory controller 200 may run firmware (FW). When the memory device 100 is a flash memory device, the memory controller 200 may run firmware such as a Flash Translation Layer (FTL) for controlling communication between the host 300 and the memory device 100.

In an embodiment, the memory controller 200 may receive data and a logical block address (LBA) from the host 300, and may translate the logical block address (LBA) into a physical block address (PBA) indicating the address of memory cells which are included in the memory device 100 and in which data is to be stored.

The memory controller 200 may control the memory device 100 so that a program operation, a read operation or an erase operation is performed in response to a request received from the host 300. During a program operation, the memory controller 200 may provide a write command, a physical block address (PBA), and data to the memory device 100. During a read operation, the memory controller 200 may provide a read command and a physical block address (PBA) to the memory device 100. During an erase operation, the memory controller 200 may provide an erase command and a physical block address (PBA) to the memory device 100.

In an embodiment, the memory controller 200 may autonomously generate a command, an address, and data regardless of whether a request from the host 300 is received, and may transmit them to the memory device 100. For example, the memory controller 200 may provide commands, addresses, and data to the memory device 100 to perform background operations, such as a program operation for wear leveling and a program operation for garbage collection.

In an embodiment, the memory controller 200 may control at least two memory devices 100. In this case, the memory controller 200 may control the memory devices 100 using an interleaving scheme to improve operating performance. The interleaving scheme may be an operating manner in which the operating periods of at least two memory devices 100 are caused to overlap each other.

The memory controller 200 may control a plurality of memory devices 100 coupled thereto through one or more channels. Each memory device 100 may include one or more planes. Each plane may include a plurality of memory blocks.

The memory controller 200 may include a sensor module which senses the movement of a vehicle and outputs a sensing value. The sensor module may include at least one of a gyroscope sensor and an acceleration sensor. The sensing value may include the tilt value of the vehicle or a variation value in the tilt value. The tilt value may be measured using the gyroscope sensor and the acceleration sensor.

The sensor module of the memory controller 200 may determine whether the sensing value measured based on the movement of the vehicle moves outside of a normal range. The memory controller 200 may control the memory device 100 so that the log information of the storage device 50 is stored in a memory block selected from among the plurality of memory blocks.

For example, the memory controller 200 may open the memory block to which log information is to be written when the sensing value moves outside of the normal range.

The memory controller 200 may control the memory device 100 so that the log information is written to the open memory block from the time point at which the sensing value moves outside of the normal range to the time point at which the sensing value returns to the normal range. In other embodiments, the memory controller 200 may control the memory device 100 so that the log information is written to the open memory block until a preset time has elapsed since the time point at which the sensing value moved outside of the normal range.

The memory controller 200 may close the selected memory block after the preset time has elapsed since the time point at which the sensing value moved outside of the normal range, or when the sensing value returns to the normal range. The memory controller 200 may close the open memory block when writing of the log information has been completed.

In accordance with an embodiment of the present disclosure, when the sensing value returns to the normal range or when the preset time has elapsed, the open memory block is forcibly closed, and thus an empty area or an invalid area in the open memory block may be reduced. That is, the space of the memory block in which the log information is stored may be efficiently utilized. Also, whenever log information is written, a new block is open, and thus the management of log information may be further simplified compared to the case in which additional log information is subsequently written to the block to which log information was previously written.

The log information of the storage device 50 may include vehicle running information and internal operation information which are obtained from the time point at which the sensing value moves outside of the normal range to the time point at which the sensing value returns back to the normal range. In an embodiment, the log information of the storage device 50 may include vehicle running information and internal operation information which are obtained during a preset time ranging from the time point at which the sensing value moves outside of the normal range.

The vehicle running information may include physical and geographic information related to vehicle driving, such as the speed, tilt, temperature, and Global Positioning System (GPS) position of a vehicle.

The internal operation information may include input/output requests and responses exchanged by the storage device 50 with the host 300. The internal operation information may include alerts provided by the storage device 50 to the host 300. The internal operation information may include interrupt information of the storage device 50. The internal operation information may include the sensing value measured using the sensor module. The internal operation information may include the time point at which the sensing value moved outside of the normal range. The internal operation information may include the time point at which a preset time has elapsed since the time point at which the sensing value moved outside of the normal range. The internal operation information may include the time point at which the sensing value, having moved outside of the normal range, returns back to the normal range.

The host 300 may communicate with the storage device 50 using at least one of various communication standards or interfaces such as universal serial bus (USB), serial AT attachment (SATA), serial attached SCSI (SAS), high speed interchip (HSIC), small computer system interface (SCSI), Peripheral Component Interconnection (PCI), PCI express (PCIe), nonvolatile memory express (NVMe), universal flash storage (UFS), secure digital (SD), multimedia card (MMC), embedded MMC (eMMC), dual in-line memory module (DIMM), registered DIMM (RDIMM), and load reduced DIMM (LRDIMM) communication methods.

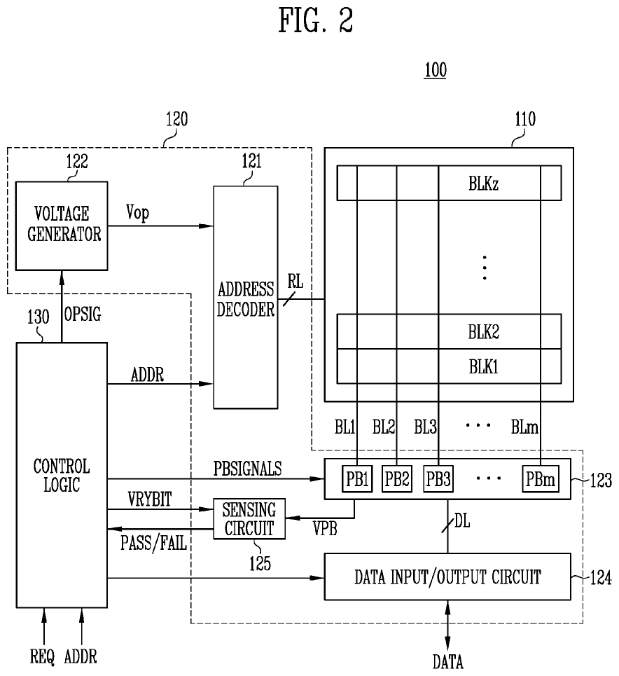

FIG. 2 is a diagram illustrating the structure of the memory device of FIG. 1 according to an embodiment of the present disclosure.

Referring to FIG. 2, the memory device 100 may include a memory cell array 110, a peripheral circuit 120, and a control logic 130.

The memory cell array 110 includes a plurality of memory blocks BLK1 to BLKz. The plurality of memory blocks BLK1 to BLKz are coupled to an address decoder 121 through row lines RL. The memory blocks BLK1 to BLKz are coupled to a read and write circuit 123 through bit lines BL1 to BLm. Each of the memory blocks BLK1 to BLKz includes a plurality of memory cells. In an embodiment, the plurality of memory cells are nonvolatile memory cells. In the plurality of memory cells, memory cells coupled to the same word line are defined as a single physical page. That is, the memory cell array 110 is composed of a plurality of physical pages. In accordance with an embodiment of the present disclosure, each of the plurality of memory blocks BLK1 to BLKz included in the memory cell array 110 may include a plurality of dummy cells. As the dummy cells, one or more dummy cells may be coupled in series between a drain select transistor and the memory cells, and between a source select transistor and the memory cells.

Each of the memory cells of the memory device 100 may be implemented as a single-level cell (SLC) capable of storing a single data bit, a multi-level cell (MLC) capable of storing two data bits, a triple-level cell (TLC) capable of storing three data bits, or a quad-level cell (QLC) capable of storing four data bits.

The peripheral circuit 120 may include the address decoder 121, a voltage generator 122, the read and write circuit 123, a data input/output circuit 124, and a sensing circuit 125.

The peripheral circuit 120 may drive the memory cell array 110. For example, the peripheral circuit 120 may drive the memory cell array 110 so that a program operation, a read operation, and an erase operation are performed.

The address decoder 121 is coupled to the memory cell array 110 through row lines RL. The row lines RL may include drain select lines, word lines, source select lines, and a common source line. In accordance with an embodiment of the present disclosure, the word lines may include normal word lines and dummy word lines. In accordance with an embodiment of the present disclosure, the row lines RL may further include a pipe select line.

The address decoder 121 may be operated under the control of the control logic 130. The address decoder 121 receives addresses ADDR from the control logic 130.

The address decoder 121 may decode a block address, among the received addresses ADDR. The address decoder 121 selects at least one of the memory blocks BLK1 to BLKz according to the decoded block address. The address decoder 121 may decode a row address among the received addresses ADDR. The address decoder 121 may select at least one of word lines of the selected memory block according to the decoded row address. The address decoder 121 may apply operating voltages Vop supplied from the voltage generator 122 to the selected word line.

During a program operation, the address decoder 121 may apply a program voltage to the selected word line and apply a pass voltage having a level lower than that of the program voltage to unselected word lines. During a program verify operation, the address decoder 121 may apply a verify voltage to a selected word line and apply a verify pass voltage having a level higher than that of the verify voltage to unselected word lines.

During a read operation, the address decoder 121 may apply a read voltage to a selected word line and apply a read pass voltage having a level higher than that of the read voltage to unselected word lines.

In accordance with an embodiment of the present disclosure, the erase operation of the memory device 100 may be performed on a memory block basis. During an erase operation, the addresses ADDR input to the memory device 100 include a block address. The address decoder 121 may decode the block address and select a single memory block in response to the decoded block address. During the erase operation, the address decoder 121 may apply a ground voltage to word lines coupled to the selected memory block.

In accordance with an embodiment of the present disclosure, the address decoder 121 may decode a column address among the received addresses ADDR. The decoded column address may be transferred to the read and write circuit 123. In an embodiment, the address decoder 121 may include components such as a row decoder, a column decoder, and an address buffer.

The voltage generator 122 may generate a plurality of operating voltages Vop using an external supply voltage that is supplied to the memory device 100. The voltage generator 122 may be operated under the control of the control logic 130.

In an embodiment, the voltage generator 122 may generate an internal supply voltage by regulating the external supply voltage. The internal supply voltage generated by the voltage generator 122 is used as an operating voltage for the memory device 100.

In an embodiment, the voltage generator 122 may generate the plurality of operating voltages Vop using the external supply voltage or the internal supply voltage. The voltage generator 122 may generate various voltages required by the memory device 100. For example, the voltage generator 122 may generate a plurality of erase voltages, a plurality of program voltages, a plurality of pass voltages, a plurality of select read voltages, and a plurality of unselect read voltages.

The voltage generator 122 may include a plurality of pumping capacitors for receiving the internal supply voltage to generate a plurality of operating voltages Vop having various voltage levels, and may generate the plurality of operating voltages Vop by selectively enabling the plurality of pumping capacitors under the control of the control logic 130.

The generated operating voltages Vop may be supplied to the memory cell array 110 by the address decoder 121.

The read and write circuit 123 includes first to m-th page buffers PB1 to PBm. The first to m-th page buffers PB1 to PBm are coupled to the memory cell array 110 through the first to m-th bit lines BL1 to BLm, respectively. The first to m-th page buffers PB1 to PBm are operated under the control of the control logic 130.

The first to m-th page buffers PB1 to PBm perform data communication with the data input/output circuit 124. During a program operation, the first to m-th page buffers PB1 to PBm receive data DATA to be stored through the data input/output circuit 124 and data lines DL.

During a program operation, the first to m-th page buffers PB1 to PBm may transfer the data DATA to be stored, received through the data input/output circuit 124, to selected memory cells through the bit lines BL1 to BLm when a program pulse is applied to a selected word line. Memory cells in a selected page are programmed based on the received data DATA.

Memory cells coupled to a bit line to which a program permission voltage (e.g., a ground voltage) is applied may have increased threshold voltages. The threshold voltages of memory cells coupled to a bit line to which a program inhibit voltage (e.g., a supply voltage) is applied may be maintained. During a program verify operation, the first to m-th page buffers PB1 to PBm read the data DATA stored in the selected memory cells from the selected memory cells through the bit lines BL1 to BLm.

During a read operation, the read and write circuit 123 may read data DATA from the memory cells in the selected page through the bit lines BL, and may store the read data DATA in the first to m-th page buffers PB1 to PBm.

During an erase operation, the read and write circuit 123 may allow the bit lines BL to float. In an embodiment, the read and write circuit 123 may include a column select circuit.

The data input/output circuit 124 is coupled to the first to m-th page buffers PB1 to PBm through the data lines DL. The data input/output circuit 124 is operated in response to the control of the control logic 130.

The data input/output circuit 124 may include a plurality of input/output buffers (not illustrated) which receive input data DATA. During a program operation, the data input/output circuit 124 receives the data DATA to be stored from an external controller (not illustrated). During a read operation, the data input/output circuit 124 outputs the data DATA, received from the first to m-th page buffers PB1 to PBm included in the read and write circuit 123, to the external controller.

During a read operation or a verify operation, the sensing circuit 125 may generate a reference current in response to an enable bit signal VRYBIT generated by the control logic 130, and may output a pass signal or a fail signal to the control logic 130 by comparing a sensing voltage VPB received from the read and write circuit 123 with a reference voltage generated by the reference current.

The control logic 130 may be coupled to the address decoder 121, the voltage generator 122, the read and write circuit 123, the data input/output circuit 124, and the sensing circuit 125. The control logic 130 may control the overall operation of the memory device 100. The control logic 130 may be operated in response to a command CMD transmitted from an external device.

The control logic 130 may control the peripheral circuit 120 by generating various types of signals in response to the command CMD and the addresses ADDR. For example, the control logic 130 may generate an operation signal OPSIG, an address ADDR, read and write circuit control signals PBSIGNALS, and an enable bit VRYBIT in response to the command CMD and the addresses ADDR. The control logic 130 may output the operation signal OPSIG to the voltage generator 122, output the address ADDR to the address decoder 121, output the read and write circuit control signals PBSIGNALS to the read and write circuit 123, and output the enable bit VRYBIT to the sensing circuit 125. In addition, the control logic 130 may determine whether a verify operation has passed or failed in response to the pass or fail signal PASS or FAIL output from the sensing circuit 125.

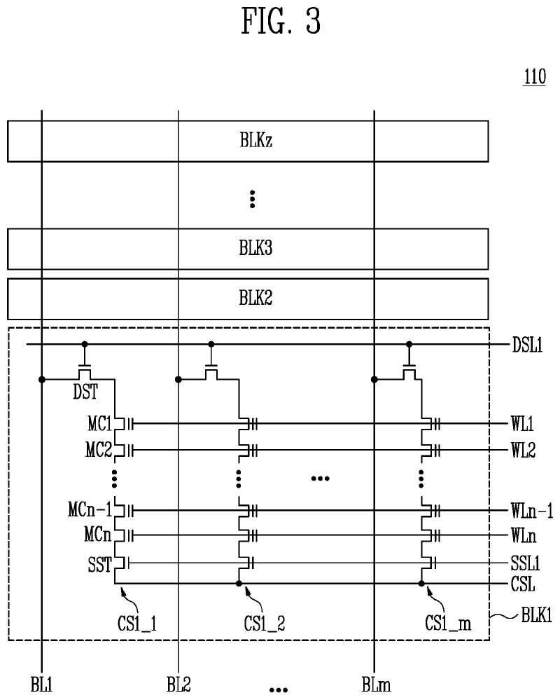

FIG. 3 is a diagram illustrating the memory cell array of FIG. 2 according to an embodiment of the present disclosure.

Referring to FIG. 3, the first to z-th memory blocks BLK1 to BLKz are coupled in common to the first to m-th bit lines BL1 to BLm. In FIG. 3, for convenience of description, elements included in the first memory block BLK1, among the plurality of memory blocks BLK1 to BLKz, are illustrated, and illustration of elements included in each of the remaining memory blocks BLK2 to BLKz is omitted. It will be understood that each of the remaining memory blocks BLK2 to BLKz has the same configuration as the first memory block BLK1.

The memory block BLK1 may include a plurality of cell strings CS1_1 to CS1_m, where m is a positive integer. The first to m-th cell strings CS1_1 to CS1_m are respectively coupled to the first to m-th bit lines BL1 to BLm. Each of the first to m-th cell strings CS1_1 to CS1_m may include a drain select transistor DST, a plurality of memory cells MC1 to MCn, where n is a positive integer, which are coupled in series to each other, and a source select transistor SST.

A gate terminal of the drain select transistor DST included in each of the first to m-th cell strings CS1_1 to CS1_m is coupled to a drain select line DSL1. Gate terminals of the first to n-th memory cells MC1 to MCn included in each of the first to m-th cell strings CS1_1 to CS1_m are coupled to first to n-th word lines WL1 to WLn, respectively. A gate terminal of the source select transistor SST included in each of the first to m-th cell strings CS1_1 to CS1_m is coupled to a source select line SSL1.

For convenience of description, the structure of each cell string will be described based on the first cell string CS1_1, among the plurality of cell strings CS1_1 to CS1_m. However, it will be understood that each of the remaining cell strings CS1_2 to CS1_m is configured in the same manner as the first cell string CS1_1.

A drain terminal of the drain select transistor DST included in the first cell string CS1_1 is coupled to the first bit line BL1. A source terminal of the drain select transistor DST included in the first cell string CS1_1 is coupled to a drain terminal of the first memory cell MC1 included in the first cell string CS1_1. The first to n-th memory cells MC1 to MCn may be coupled in series to each other. A drain terminal of the source select transistor SST included in the first cell string CS1_1 is coupled to a source terminal of the n-th memory cell MCn included in the first cell string CS1_1. A source terminal of the source select transistor SST included in the first cell string CS1_1 is coupled to a common source line CSL. In an embodiment, the common source line CSL may be coupled in common to the first to z-th memory blocks BLK1 to BLKz.

The drain select line DSL1, the first to n-th word lines WL1 to WLn, and the source select line SSL1 are included in the row lines RL of FIG. 2. The drain select line DSL1, the first to n-th word lines WL1 to WLn, and the source select line SSL1 are controlled by the address decoder 121. The common source line CSL is controlled by the control logic 130. The first to m-th bit lines BL1 to BLm are controlled by the read and write circuit 123.

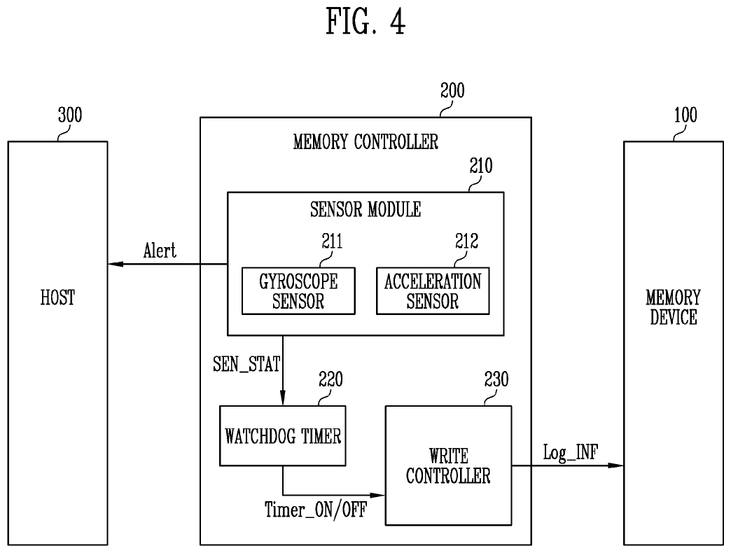

FIG. 4 is a diagram illustrating the configuration and operation of a memory controller according to an embodiment of the present disclosure.

Referring to FIG. 4, the memory controller 200 may include a sensor module 210, a watchdog timer 220, and a write controller 230.

The sensor module 210 may include a gyroscope sensor 211 and an acceleration sensor 212.

The number and type of sensors included in the sensor module 210 are not limited to the present embodiment. For example, the sensor module 210 may include various sensors configured to acquire information related to movement of a vehicle, such as a temperature sensor, a humidity sensor, a pressure sensor, a speed sensor, a global positioning system (GPS), and an inertial navigation system.

The sensor module 210 may acquire a sensing value using the gyroscope sensor 211 and the acceleration sensor 212. The sensing value may include at least one of the tilt value of a vehicle and a variation value in the tilt value. The type of the sensing value is not limited to the present embodiment.

The sensor module 210 may output the sensing value measured based on the movement of the vehicle. The sensor module 210 may provide an alert to the host 300 when the sensing value moves outside of a normal range.

For example, when the degree to which the sensing value moves outside of the normal range is equal to or greater than a first reference value and less than a second reference value, the sensor module 210 may provide the host 300 with an alert indicating that a tilt occurs depending on the difference between air pressures of respective tires of the vehicle. When the degree to which the sensing value moves outside of the normal range is equal to or greater than the second reference value and less than a third reference value, the sensor module 210 may provide the host 300 with an alert indicating that the vehicle is making an abrupt turn at an excessive speed. When the degree to which the sensing value moves outside of the normal range is equal to or greater than the third reference value and less than a fourth reference value, the sensor module 210 may provide the host 300 with an alert indicating that the vehicle has overturned.

The sensor module 210 may provide a sensor status signal SEN_STAT, indicating whether the sensing value is outside of the normal range, to the watchdog timer 220.

The watchdog timer 220 may be turned on or off in response to the sensor status signal SEN_STAT. The watchdog timer 220 may be turned on from the time point at which the sensing value moves outside of the normal range. The watchdog timer 220 may be turned off when a preset time has elapsed since the time point at which the sensing value moved outside of the normal range. The watchdog timer 220 may be turned off when the sensing value, having moved outside of the normal range, returns to the normal range.

The watchdog timer 220 may provide a timer on/off signal Timer_ON/OFF, indicating whether the timer has been turned on or off, to the write controller 230.

The write controller 230 may determine, based on the timer on/off signal Timer_ON/OFF, whether the watchdog timer 220 has been turned on or off. When the watchdog timer 220 is turned on, the write controller 230 may open a memory block selected from among a plurality of memory blocks included in the memory device 100. The write controller 230 may collect log information Log_INF while communicating with the sensor module 210 and the watchdog timer 220. The write controller 230 may control the memory device 100 so that the collected log information Log_INF is written to the open memory block until the watchdog timer 220 is turned off. The write controller 230 may close the selected memory block when the watchdog timer 220 is turned off. Before the log information Log_INF is written to the selected memory block, it may be temporarily stored in a buffer memory (not illustrated) of the memory controller 200.

The write controller 230 may control the memory device so that the log information Log_INF of the storage device, which is obtained from the time point at which the watchdog timer 220 is turned on to the time point at which the watchdog timer 220 is turned off, is stored in the selected memory block. The write controller 230 may control the memory device 100 so that the log information Log_INF, which is obtained from the time point at which the sensing value moves outside of the normal range to the time point at which the sensing value returns to the normal range, is stored in the selected memory block. Alternatively, the write controller 230 may control the memory device 100 so that log information Log_INF, which is obtained from the time point at which the sensing value moves outside of the normal range to the time point at which a preset time has elapsed since the same, is stored in the selected memory block.

In an embodiment, the log information Log_INF may include input/output requests and responses exchanged with the host 300. The log information Log_INF may include alerts provided to the host 300. The log information Log_INF may include interrupt information of the storage device. The log information Log_INF may include vehicle running information. The vehicle running information may include physical and geographic information related to vehicle driving, such as the speed, tilt, temperature, and GPS position of a vehicle. The vehicle running information may be used as data required in order to determine whether the vehicle is speeding, defects have occurred in the vehicle, or a vehicle accident has occurred. The log information Log_INF may include the sensing value. The log information Log_INF may include the time point at which the watchdog timer is turned on and the time point at which the watchdog timer is turned off.

The write controller 230 may perform a garbage collection operation on target blocks in which the log information Log_INF is stored. For example, the write controller 230 may control the memory device 100 so that valid data, stored in the target blocks, is stored in an additional memory block.

In an embodiment, the write controller 230 may be configured to, when the number of target blocks in which the log information Log_INF is stored is equal to or greater than the reference number of target blocks, store the valid data, stored in the target blocks, in an additional memory block. Alternatively, the write controller 230 may be configured to, when the size of the log information Log_INF stored in the target blocks is equal to or greater than a reference size, store the valid data, stored in the target blocks, in an additional memory block. The garbage collection operation may prevent a run-out of spare (ROS) state, in which there are not enough memory blocks to store the log information, from occurring.

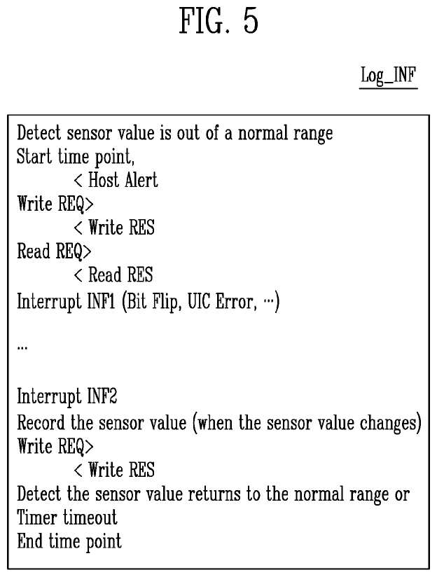

FIG. 5 is a diagram illustrating log information according to an embodiment of the present disclosure.

Referring to FIG. 5, log information may include internal operation information of a storage device and vehicle running information, which are obtained from the time point at which a sensing value moves outside of a normal range to the time point at which the sensing value returns to the normal range. Alternatively, the log information may include internal operation information of the storage device and vehicle running information, which are obtained until a time-out event occurs after a preset time has elapsed since the time point at which the sensing value moved outside of the normal range.

In FIG. 5, the log information may include records indicating that a sensing value that has moved outside of the normal range is detected. The log information may include a start time point, indicating the time point at which the sensing value moves outside of the normal range. The log information may include records of alerts provided to a host. The log information may include records of write requests received from the host. The log information may include records of responses to the write requests, provided to the host. The log information may include records of read requests received from the host. The log information may include records of responses to the read requests, provided to the host. The log information may include first interrupt information. The interrupt information may include information about a bit flip error occurring in an error correction code (ECC) process, a UFS Interconnection Layer (UIC) error, or the like.

The log information may include second interrupt information. The log information may include records of a changed sensing value whenever the sensing value changes. The log information may include records of responses to write requests, provided to the host. The log information may include records of read requests received from the host.

The log information may include records indicating that the sensing value, having moved outside of the normal range, has returned to the normal range. Alternatively, the log information may include records indicating that a time-out event has occurred when a preset time has elapsed since the watchdog timer was turned on. The log information may include an end time point indicating the time point at which the watchdog timer is turned off. The log information may include the time point at which the writing of the log information is terminated.

Examples of the log information are not limited to the present embodiment. The log information may include vehicle running information, in addition to the internal operation information of the storage device. The vehicle running information may include physical and geographic information related to vehicle driving, such as the speed, tilt, temperature, and GPS position of a vehicle.

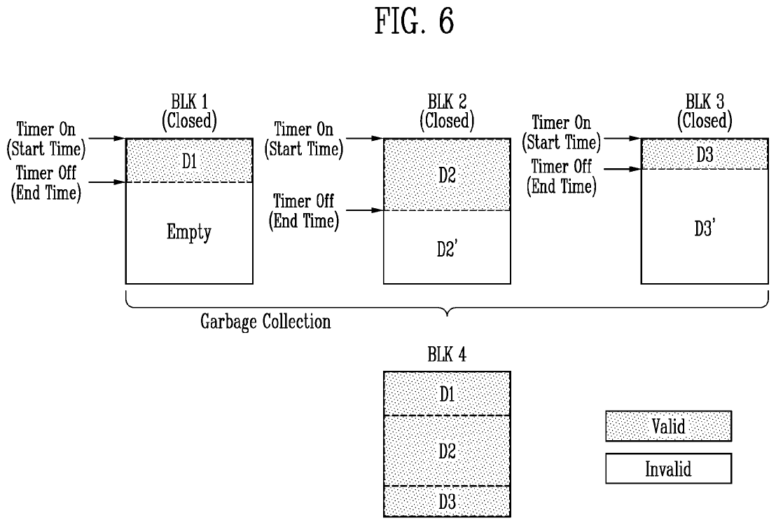

FIG. 6 is a diagram illustrating a garbage collection operation performed on target blocks according to an embodiment of the present disclosure.

Referring to FIG. 6, memory blocks BLK 1 to BLK 3 may be target blocks in which log information is stored. The amount of log information stored in each of the memory blocks BLK 1 to BLK 3 may differ depending on the time point at which a timer is turned on or off when the log information is written to the corresponding memory block.

The memory block BLK 1 may store valid data D1, and the remaining area thereof may be empty space. The memory block BLK2 may store valid data D2 and invalid data D2′. The memory block BLK3 may store valid data D3 and invalid data D3′. D1 to D3 may be pieces of log information stored in respective memory blocks.

In an embodiment, the reference number of memory blocks, which is the criterion for performing a garbage collection operation, may be 3. Because the number of memory blocks BLK 1 to BLK 3 in which the log information is stored is 3, which is equal to or greater than the reference number of memory blocks, the criterion for performing the garbage collection operation may be satisfied. Therefore, the garbage collection operation of storing the valid data D1, D2, and D3, stored in the memory blocks BLK 1 to BLK 3, in an additional memory block BLK4 may be performed.

In an embodiment, a reference size, which is a criterion for performing the garbage collection operation, may be 1. The reference size is not limited to that of the present embodiment. Since the size of the valid data D1, D2, and D3, indicating the log information stored in the memory blocks BLK 1 to BLK 3, is the reference size, the criterion for performing a garbage collection operation may be satisfied. Therefore, the garbage collection operation of storing the valid data D1, D2, and D3, stored in the memory blocks BLK 1 to BLK 3, in an additional memory block BLK4 may be performed.

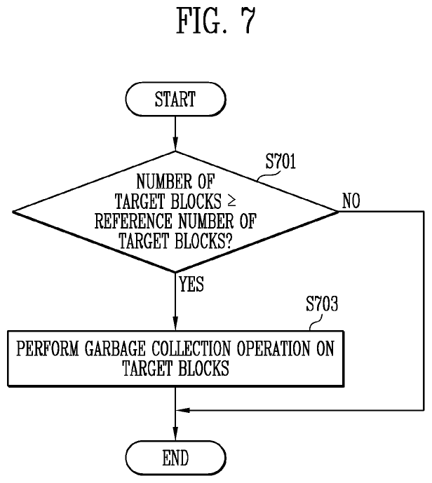

FIG. 7 is a flowchart illustrating a garbage collection operation according to an embodiment of the present disclosure.

Referring to FIG. 7, at operation S701, a storage device may determine whether the number of closed target blocks in which log information is stored is equal to or greater than the reference number of target blocks. When it is determined that the number of target blocks is equal to or greater than the reference number of target blocks, the operation proceeds to operation S703, whereas when it is determined that the number of target blocks is less than the reference number of target blocks, the operation is terminated.

At operation S703, the storage device may perform a garbage collection operation on the target blocks.

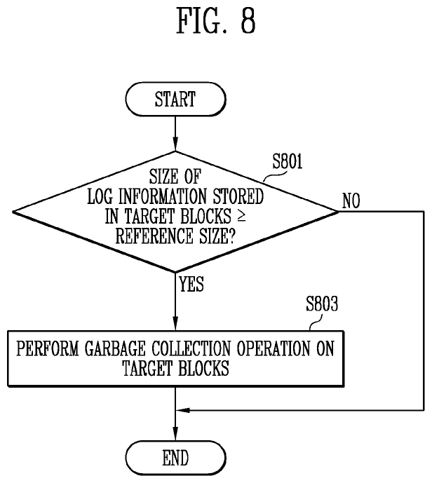

FIG. 8 is a flowchart illustrating a garbage collection operation according to an embodiment of the present disclosure.

Referring to FIG. 8, at operation S801, a storage device may determine whether the size of log information stored in closed target blocks is equal to or greater than a reference size. When it is determined that the size of the log information is equal to or greater than the reference size, the operation proceeds to operation S803, whereas when it is determined that the size of the log information is less than the reference size, the operation is terminated.

At operation S803, the storage device may perform a garbage collection operation on the target blocks.

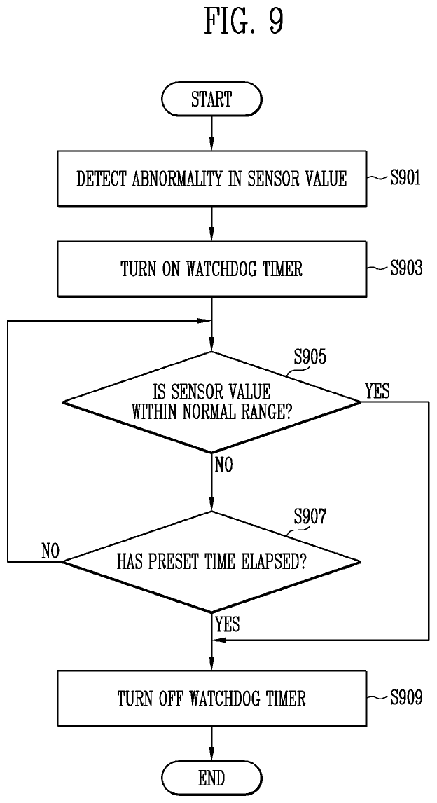

FIG. 9 is a flowchart illustrating on and off operation of a watchdog timer according to an embodiment of the present disclosure.

Referring to FIG. 9, at operation S901, the storage device may detect an abnormality in a sensing value. For example, when the sensing value moves outside of a normal range, it may be determined that an abnormality is present in the sensing value.

At operation S903, the storage device may turn on a watchdog timer.

At operation S905, the storage device may determine whether the sensing value is within a normal range. For example, the storage device may determine whether the sensing value, having moved outside of the normal range at operation S901, has returned to the normal range. When it is determined that the sensing value is within the normal range, the operation proceeds to operation S909, whereas when it is determined that the sensing value has moved outside of the normal range, the operation proceeds to operation S907.

At operation S907, the storage device may determine whether a preset time has elapsed since the time point at which the watchdog timer was turned on. When it is determined that the preset time has elapsed since the time point at which the watchdog timer was turned on, the operation proceeds to operation S909, whereas when it is determined that the preset time has not elapsed, the operation returns to operation S905.

At operation S909, the storage device may turn off the watchdog timer.

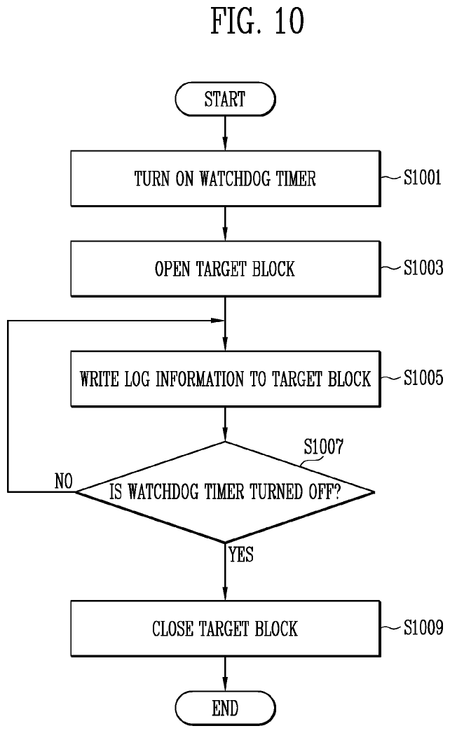

FIG. 10 is a flowchart illustrating the operation of a storage device according to an embodiment of the present disclosure.

Referring to FIG. 10, at operation S1001, the storage device may turn on a watchdog timer.

At operation S1003, the storage device may open the target block in which log information is to be stored, among a plurality of memory blocks.

At operation S1005, the storage device may write the log information to the target block.

At operation S1007, the storage device may determine whether the watchdog timer is turned off. When it is determined that the watchdog timer is turned off, the operation proceeds to operation S1009, whereas when it is determined that the watchdog timer remains turned on, the operation returns to operation S1005.

At operation S1009, the storage device may terminate writing of the log information to the target block, and may close the target block.

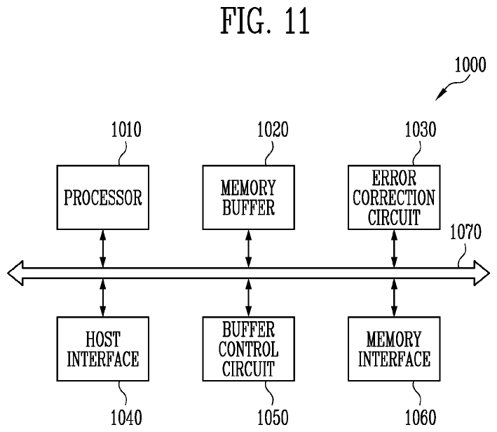

FIG. 11 is a diagram illustrating the memory controller of FIG. 1 according to an embodiment of the present disclosure.

Referring to FIG. 11, a memory controller 1000 is coupled to a host and a memory device. In response to a request from the host, the memory controller 1000 may access the memory device. For example, the memory controller 1000 may control read, write, erase, and background operations of the memory device. The memory controller 1000 may provide an interface between the memory device and the host. The memory controller 1000 may run firmware for controlling the memory device.

The memory controller 1000 may include a processor 1010, a memory buffer 1020, an error correction circuit (ECC) 1030, a host interface 1040, a buffer control circuit 1050, a memory interface 1060, and a bus 1070.

The bus 1070 may provide a channel between components of the memory controller 1000.

The processor 1010 may control the overall operation of the memory controller 1000 and perform a logical operation. The processor 1010 may communicate with an external host through the host interface 1040 and also communicate with the memory device through the memory interface 1060. Further, the processor 1010 may communicate with the memory buffer 1050 through the buffer control circuit 1020. The processor 1010 may control the operation of the storage device by using the memory buffer 1020 as a working memory, a cache memory or a buffer memory.

The processor 1010 may perform a function of a flash translation layer (FTL). The processor 1010 may translate a logical block address (LBA), provided by the host, into a physical block address (PBA) through the FTL. The FTL may receive the LBA using a mapping table and translate the LBA into the PBA. Examples of an address mapping method performed through the FTL may include various methods according to a mapping unit. Representative address mapping methods include a page mapping method, a block mapping method, and a hybrid mapping method.

The processor 1010 may randomize data received from the host. For example, the processor 1010 may use a randomizing seed to randomize data received from the host. The randomized data may be provided, as data to be stored, to the memory device and may be programmed in the memory cell array.

The processor may derandomize the data received from the memory device during a read operation. For example, the processor 1010 may derandomize the data received from the memory device using a derandomizing seed. Derandomized data may be output to the host.

In an embodiment, the processor 1010 may run software or firmware to perform the randomizing or derandomizing operation.

The memory buffer 1020 may be used as a working memory, a cache memory, or a buffer memory of the processor 1010. The memory buffer 1020 may store codes and commands that are executed by the processor 1010. The memory buffer 1020 may store data that is processed by the processor 1010. The memory buffer 1020 may include a static RAM (SRAM) or a dynamic RAM (DRAM).

The error correction circuit 1030 may perform error correction. The error correction circuit 1030 may perform error correction code (ECC) encoding based on data to be written to the memory device through the memory interface 1060. The ECC-encoded data may be transferred to the memory device through the memory interface 1060. The error correction circuit 1030 may perform ECC decoding based on data received from the memory device through the memory interface 1060. In an example, the error correction circuit 1030 may be included, as the component of the memory interface 1060, in the memory interface 1060.

The host interface 1040 may communicate with the external host under the control of the processor 1010. The host interface 1040 may perform communication using at least one of various communication standards or interfaces such as universal serial bus (USB), serial AT attachment (SATA), serial attached SCSI (SAS), high speed Interchip (HSIC), small computer system interface (SCSI), peripheral component Interconnection (PCI), PCI express (PCIe), nonvolatile Memory express (NVMe), universal flash storage (UFS), secure digital (SD), multimedia card (MMC), embedded MMC (eMMC), dual in-line memory module (DIMM), registered DIMM (RDIMM), and load reduced DIMM (LRDIMM) communication methods.

The buffer control circuit 1050 may control the memory buffer 1020 under the control of the processor 1010.

The memory interface 1060 may communicate with the memory device under the control of the processor 1010. The memory interface 1060 may transmit/receive commands, addresses, and data to/from the memory device through channels.

In an embodiment, the memory controller 1000 may not include the memory buffer 1020 and the buffer control circuit 1050.

In an embodiment, the processor 1010 may control the operation of the memory controller 1000 using codes. The processor 1010 may load codes from a nonvolatile memory device (e.g., ROM) provided in the memory controller 1000. In an embodiment, the processor 1010 may load codes from the memory device through the memory interface 1060.

In an embodiment, the bus 1070 of the memory controller 1000 may be divided into a control bus and a data bus. The data bus may transmit data in the memory controller 1000, and the control bus may transmit control information, such as commands or addresses, in the memory controller 1000. The data bus and the control bus may be separated from each other, and may neither interfere with each other nor influence each other. The data bus may be coupled to the host interface 1040, the buffer control circuit 1050, the error correction circuit 1030, and the memory interface 1060. The control bus may be coupled to the host interface 1040, the processor 1010, the buffer control circuit 1050, the memory buffer 1020, and the memory interface 1060.

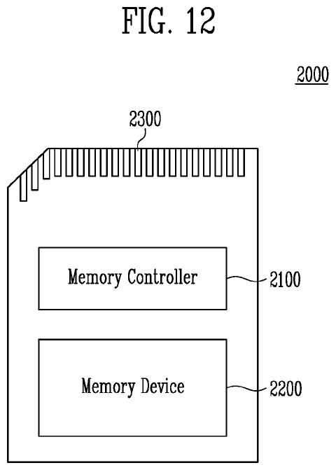

FIG. 12 is a block diagram illustrating a memory card system to which a storage device according to an embodiment of the present disclosure is applied.

Referring to FIG. 12, a memory card system 2000 may include a memory controller 2100, a memory device 2200, and a connector 2300.

The memory controller 2100 is coupled to the memory device 2200. The memory controller 2100 may access the memory device 2200. For example, the memory controller 2100 may control read, write, erase, and background operations of the memory device 2200. The memory controller 2100 may provide an interface between the memory device 2200 and a host. The memory controller 2100 may run firmware for controlling the memory device 2200. The memory controller 2100 may be implemented in the same manner as the memory controller 200, described above with reference to FIG. 1.

In an embodiment, the memory controller 2100 may include components, such as a RAM, a processor, a host interface, a memory interface, and an error correction circuit.

The memory controller 2100 may communicate with an external device through the connector 2300. The memory controller 2100 may communicate with an external device (e.g., a host) based on a specific communication protocol. In an embodiment, the memory controller 2100 may communicate with the external device through at least one of various communication standards or interfaces such as universal serial bus (USB), multimedia card (MMC), embedded MMC (eMMC), peripheral component interconnection (PCI), PCI-express (PCI-e or PCIe), an advanced technology attachment (ATA) protocol, a serial-ATA (SATA), parallel-ATA (PATA), small computer system interface (SCSI), enhanced small disk interface (ESDI), integrated drive electronics (IDE), firewire, universal flash storage (UFS), Wi-Fi, Bluetooth, and nonvolatile memory express (NVMe) protocols. In an embodiment, the connector 2300 may be defined by at least one of the above-described various communication protocols.

In an embodiment, the memory device 2200 may be implemented as any of various nonvolatile memory devices, such as an electrically erasable and programmable ROM (EEPROM), a NAND flash memory, a NOR flash memory, a phase-change RAM (PRAM), a resistive RAM (ReRAM), a ferroelectric RAM (FRAM), and a spin transfer torque magnetic RAM (STT-MRAM).

The memory controller 2100 and the memory device 2200 may be integrated into a single semiconductor device to form a memory card. For example, the memory controller 2100 and the memory device 2200 may be integrated into a single semiconductor device and may then form a memory card such as a personal computer memory card international association (PCMCIA), a compact flash card (CF), a smart media card (SM or SMC), a memory stick multimedia card (MMC, RS-MMC, MMCmicro or eMMC), a SD card (SD, miniSD, microSD, or SDHC), a universal flash storage (UFS), or the like.

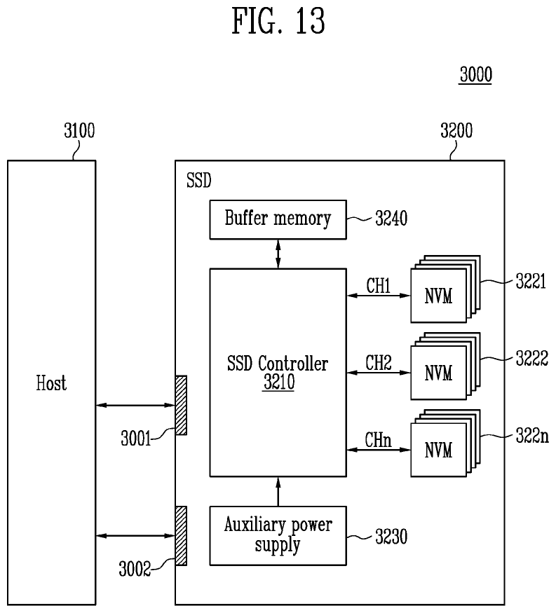

FIG. 13 is a block diagram illustrating a solid state drive (SSD) system to which a storage device according to an embodiment of the present disclosure is applied.

Referring to FIG. 13, an SSD system 3000 may include a host 3100 and an SSD 3200. The SSD 3200 may exchange a signal SIG with the host 3100 through a signal connector 3001, and may receive power PWR through a power connector 3002. The SSD 3200 may include an SSD controller 3210, a plurality of flash memories 3221 to 322n, an auxiliary power supply 3230, and a buffer memory 3240.

In accordance with an embodiment of the present disclosure, the SSD controller 3210 may perform the function of the memory controller 200, described above with reference to FIG. 1.

The SSD controller 3210 may control the plurality of flash memories 3221 to 322n in response to the signal SIG received from the host 3100. In an embodiment, the signal SIG may indicate signals based on the interfaces of the host 3100 and the SSD 3200. For example, the signal SIG may be a signal defined by at least one of various communication standards or interfaces such as universal serial bus (USB), multimedia card (MMC), embedded MMC (eMMC), peripheral component interconnection (PCI), PCI-express (PCI-e or PCIe), an advanced technology attachment (ATA), serial-ATA (SATA), parallel-ATA (PATA), small computer system interface (SCSI), enhanced small disk interface (ESDI), integrated drive electronics (IDE), firewire, universal flash storage (UFS), Wi-Fi, Bluetooth, and nonvolatile memory express (NVMe) interfaces.

The auxiliary power supply 3230 may be coupled to the host 3100 through the power connector 3002. The auxiliary power supply 3230 may be supplied with power PWR from the host 3100, and may be charged. The auxiliary power supply 3230 may supply the power of the SSD 3200 when the supply of power from the host 3100 is not smoothly performed. In an embodiment, the auxiliary power supply 3230 may be located inside the SSD 3200 or located outside the SSD 3200. For example, the auxiliary power supply 3230 may be located in a main board, and may also provide auxiliary power to the SSD 3200.

The buffer memory 3240 functions as a buffer memory of the SSD 3200. For example, the buffer memory 3240 may temporarily store data received from the host 3100 or data received from the plurality of flash memories 3221 to 322n, or may temporarily store metadata (e.g., mapping tables) of the flash memories 3221 to 322n. The buffer memory 3240 may include volatile memories, such as DRAM, SDRAM, DDR SDRAM, LPDDR SDRAM, and GRAM, or nonvolatile memories, such as FRAM, ReRAM, STT-MRAM, and PRAM.

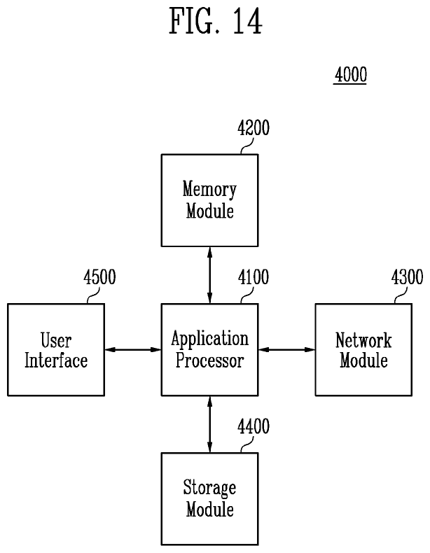

FIG. 14 is a block diagram illustrating a user system to which a storage device according to an embodiment of the present disclosure is applied.

Referring to FIG. 14, a user system 4000 may include an application processor 4100, a memory module 4200, a network module 4300, a storage module 4400, and a user interface 4500.

The application processor 4100 may run components included in the user system 4000, an Operating System (OS) or a user program. In an embodiment, the application processor 4100 may include controllers, interfaces, graphic engines, etc. for controlling the components included in the user system 4000. The application processor 4100 may be formed of a system-on-chip (SoC).

The memory module 4200 may act as a main memory, a working memory, a buffer memory or a cache memory of the user system 4000. The memory module 4200 may include volatile RAMs such as DRAM, SDRAM, DDR SDRAM, DDR2 SDRAM, DDR3 SDRAM, LPDDR SDARM, LPDDR2 SDRAM, and LPDDR3 SDRAM or nonvolatile RAMs such as PRAM, ReRAM, MRAM, and FRAM. In an embodiment, the application processor 4100 and the memory module 4200 may be packaged based on a package-on-package (POP), and may then be provided as a single semiconductor package.

The network module 4300 may communicate with external devices. In an embodiment, the network module 4300 may support wireless communication, such as Code Division Multiple Access (CDMA), Global System for Mobile communication (GSM), wideband CDMA (WCDMA), CDMA-2000, time division multiple access (TDMA), long term evolution (LTE), WiMAX, WLAN, UWB, Bluetooth, or Wi-Fi. In an embodiment, the network module 4300 may be included in the application processor 4100.

The storage module 4400 may store data. For example, the storage module 4400 may store data received from the application processor 4100. Alternatively, the storage module 4400 may transmit the data stored in the storage module 4400 to the application processor 4100. In an embodiment, the storage module 4400 may be implemented as a nonvolatile semiconductor memory device, such as a phase-change RAM (PRAM), a magnetic RAM (MRAM), a resistive RAM (RRAM), a NAND flash memory, a NOR flash memory, or a NAND flash memory having a three-dimensional (3D) structure. In an embodiment, the storage module 4400 may be provided as a removable storage medium (removable drive), such as a memory card or an external drive of the user system 4000.

In an embodiment, the storage module 4400 may include a plurality of nonvolatile memory devices, each of which may be operated in the same manner as the memory device 100, described above with reference to FIG. 1. The storage module 4400 may be operated in the same manner as the storage device 50, described above with reference to FIG. 1.

The user interface 4500 may include interfaces which input data or instructions to the application processor 4100 or output data to an external device. In an embodiment, the user interface 4500 may include user input interfaces such as a keyboard, a keypad, a button, a touch panel, a touch screen, a touch pad, a touch ball, a camera, a microphone, a gyroscope sensor, a vibration sensor, and a piezoelectric element. The user interface 4500 may further include user output interfaces such as an a Liquid Crystal Display (LCD), an organic light emitting diode (OLED) display device, an active matrix OLED (AMOLED) display device, an LED, a speaker, and a monitor.

In accordance with the present disclosure, there is provided a storage device for automatically recording log information depending on a sensing value and a method of operating the storage device.

While the present invention has been described with respect to the specific embodiments, it will be apparent to those skilled in the art that various changes and modifications may be made without departing from the spirit and scope of the invention as defined in the following claims. Furthermore, the embodiments may be combined to form additional embodiments.

What is claimed is:

1. A memory controller for controlling a memory device including a plurality of memory blocks, the memory controller comprising:
a sensor module configured to output a sensing value measured based on movement of a vehicle;
a watchdog timer turned on from a time point at which the sensing value moves outside of a normal range; and
a write controller configured to store log information buffered in the memory controller into a memory block selected from among the plurality of memory blocks, the log information being obtained from a time point at which the watchdog timer is turned on to a time point at which the watchdog timer is turned off.

2. The memory controller according to claim 1, wherein the watchdog timer is turned off when a preset time has elapsed since the time point at which the sensing value moved outside of the normal range, or when the sensing value returns to the normal range.

3. The memory controller according to claim 1, wherein the log information includes at least one of input/output request and response exchanged with a host, an alert provided to the host, interrupt information of the memory controller, running information of the vehicle, the sensing value, and the turn-on and turn-off time points of the watchdog timer.

4. The memory controller according to claim 1, wherein the sensor module is further configured to provide an alert to a host when the sensing value moves outside of the normal range.

5. The memory controller according to claim 1, wherein the sensor module comprises at least one of a gyroscope sensor and an acceleration sensor.

6. The memory controller according to claim 1, wherein the sensing value includes at least one of a tilt value of the vehicle and a variation value in the tilt value.

7. The memory controller according to claim 1, wherein the write controller stores the log information by:
opening the selected memory block when the watchdog timer is turned on, and
closing the selected memory block when the watchdog timer is turned off.

8. The memory controller according to claim 1, wherein the write controller is further configured to perform a garbage collection operation on target blocks storing the log information when a number of the target blocks is equal to or greater than a reference number.

9. The memory controller according to claim 1, wherein the write controller is further configured to perform a garbage collection operation on target blocks storing the log information when a size of the log information is equal to or greater than a reference size.

10. A storage device, comprising:
a memory device including a plurality of memory blocks; and
a memory controller configured to control the memory device to store log information of the storage device into a memory block selected from among the plurality of memory blocks,
wherein the memory controller is further configured to:
measure a sensing value based on movement of a vehicle, and
obtain, from a first time point at which the sensing value moves outside of a normal range, the log information during a preset time or the log information until the sensing value returns to the normal range.

11. The storage device according to claim 10, wherein the log information includes at least one of input/output request and response exchanged with a host, an alert provided to the host, interrupt information of the storage device, running information of the vehicle, the sensing value, the first time point, a second time point at which a preset time has elapsed since the first time point, and a third time point at which the sensing value returns to the normal range.

12. The storage device according to claim 10,
wherein the memory controller is further configured to provide an alert to a host when the sensing value moves outside of the normal range, and
wherein the sensing value includes at least one of a tilt value of the vehicle and a variation value in the tilt value.

13. The storage device according to claim 10, wherein the memory controller controls the memory device by instructing the memory device to:
open the selected memory block when the sensing value moves outside of the normal range, and
close the selected memory block when a preset time has elapsed since the first time point or when the sensing value returns to the normal range.

14. A method of operating a storage device including a plurality of memory blocks, the method comprising:
measuring a sensing value based on movement of a vehicle;
turning on a watchdog timer from a time point at which the sensing value moves outside of a normal range; and
storing log information of the storage device into a memory block selected from among the plurality of memory blocks, the log information being obtained from a time point at which the watchdog timer is turned on to a time point at which the watchdog timer is turned off.

15. The method according to claim 14, further comprising turning off the watchdog timer when a preset time has elapsed since the time point at which the sensing value moved outside of the normal range, or when the sensing value returns to the normal range.

16. The method according to claim 14, further comprising providing an alert to a host when the sensing value moves outside of the normal range.

17. The method according to claim 14, wherein the log information includes at least one of input/output request and response exchanged with a host, an alert provided to the host, interrupt information of the storage device, running information of the vehicle, the sensing value, and the turn-on and turn-off time points of the watchdog timer.

18. The method according to claim 14, wherein the sensing value includes at least one of a tilt value of the vehicle and a variation value in the tilt value.

19. The method according to claim 14, wherein the storing of the log information in the selected memory block comprises:
opening the selected memory block when the watchdog timer is turned on;
writing the log information to the selected memory block; and
closing the selected memory block when the watchdog timer is turned off.

20. The method according to claim 14, further comprising performing a garbage collection operation on target blocks storing the log information when a number of the target blocks is equal to or greater than a reference number or when a size of the log information is equal to or greater than a reference size.
